(19) United States
(12) Patent Application Publication
(10) Pub. No.: US 2026/0314235 A1
(43) Pub. Date: Oct. 8, 2026

(54) DISPLAY PANEL AND ELECTRONIC DEVICE INCLUDING THE SAME

(71) Applicant: Samsung Display Co., Ltd., Yongin-si (KR)

(72) Inventors: SOYOUNG OH, Yongin-si (KR); CHANGYEONG SONG, Yongin-si (KR); JONGWOO KIM, Yongin-si (KR); HYUNSUP YOON, Yongin-si (KR); SEULGEE LEE, Yongin-si (KR); WOOSUK JUNG, Yongin-si (KR); JAEHEUNG HA, Yongin-si (KR)

(21) Appl. No.: 19/422,118

(22) Filed: Dec. 16, 2025

(30) Foreign Application Priority Data
Apr. 2, 2025 (KR) 10-2025-0043129

(51) Int. Cl. H10K 59/80; H10K 59/122; H10K 102/00

(52) U.S. Cl. CPC H10K 59/8723; H10K 59/122; H10K 59/873; H10K 2102/351

(57) ABSTRACT

A display panel includes: a base substrate including an emission area and a non-emission area around the emission area; a light emitting element layer including a pixel defining film defining the emission area and on the base substrate; an encapsulation substrate on the light emitting element layer; and a filling material between the light emitting element layer and the encapsulation substrate. The light emitting element layer further includes a spacer on the pixel defining film, a capping layer on the spacer and overlapping the emission area and the non-emission area on a plane, and a barrier layer on the capping layer and overlapping the emission area and the non-emission area on a plane. The barrier layer covers the capping layer and includes a first barrier layer and a second barrier layer on the first barrier layer and having a lower density than that of the first barrier layer.

### CROSS-REFERENCE TO RELATED APPLICATION

The present application claims priority to and the benefit of Korean Patent Application No. 10-2025-0043129, filed on Apr. 2, 2025, in the Korean Intellectual Property Office, the entire content of which is incorporated herein by reference.

### BACKGROUND

### 1. Field

One or more embodiments of the present disclosure relate to a display panel and an electronic device including the same, for example, to a display panel including a barrier layer, and an electronic device including the display panel.

### 2. Description of Related Art

Multimedia electronic devices such as televisions, mobile phones, tablet computers, navigation units, and/or game consoles, include display panels that present (provide) visual content (images) to users through display screens.

A display panel includes a base substrate on which light emitting elements are arranged, an encapsulation substrate that seals the light emitting elements, and a filling material filled between the base substrate and the encapsulation substrate.

### SUMMARY

One or more aspects of embodiments of the present disclosure are directed toward a display panel with improved reliability.

One or more aspects of embodiments of the present disclosure are directed toward an electronic device with improved reliability.

Additional aspects will be set forth in part in the description which follows and, in part, will be apparent from the description, or may be learned by practice of the presented embodiments.

According to one or more embodiments of the present disclosure, a display panel includes: a base substrate including an emission area and a non-emission area which surrounds (e.g., is around) the emission area; a light emitting element layer including a pixel defining film which defines the emission area and is on (e.g., arranged on) the base substrate, a first electrode on (e.g., arranged on) the base substrate, an emission layer on (e.g., arranged on) the first electrode, and a second electrode on (e.g., arranged on) the emission layer; an encapsulation substrate on (e.g., arranged on) the light emitting element layer; and a filling material between (e.g., arranged between) the light emitting element layer and the encapsulation substrate. The light emitting element layer further includes a spacer on (e.g., arranged on the pixel defining film), a capping layer on (e.g., arranged on) the spacer and overlapping the emission area and the non-emission area on a plane (e.g., in plan view), and a barrier layer on (e.g., arranged on) the capping layer and overlapping the emission area and the non-emission area on a plane (e.g., in plan view). The barrier layer covers the capping layer and includes a first barrier layer and a second barrier layer on (e.g., arranged on) the first barrier layer. A density of the first barrier layer is higher than a density of the second barrier layer.

In one or more embodiments, a cross-section of the spacer may have a reversed trapezoidal shape.

In one or more embodiments, a thickness of the second barrier layer may be larger than a thickness of the first barrier layer.

In one or more embodiments, the spacer and the filling material may be spaced and/or apart (e.g., spaced apart or separated) from each other with the capping layer and the barrier layer arranged between the spacer and the filling material.

In one or more embodiments, the second barrier layer may include a same material as the first barrier layer.

In one or more embodiments, a thickness of the first barrier layer may be about 10 angstroms (Å) to about 20 Å.

In one or more embodiments, a thickness of the second barrier layer may be about 10% or less of a thickness of the filling material.

In one or more embodiments, the spacer may include a top surface adjacent to the encapsulation substrate, a bottom surface adjacent to the base substrate, and a side surface which connects the top surface to the bottom surface, and a thickness of the barrier layer on (e.g., arranged on) the top surface of the spacer and a thickness of the barrier layer on (e.g., arranged on) the side surface of the spacer may be the same.

In one or more embodiments, the first barrier layer may be formed through an atomic layer deposition (ALD) process, and the second barrier layer may be formed through a chemical vapor deposition (CVD) process.

According to one or more embodiments of the present disclosure, a display panel includes: a base substrate including an emission area and a non-emission area which surrounds (is around) the emission area; a light emitting element layer including a pixel defining film which defines the emission area and is on (e.g., arranged on) the base substrate; a first electrode on (e.g., arranged on) the base substrate, an emission layer on (e.g., arranged on the first electrode), and a second electrode on (e.g., arranged on) the emission layer; an encapsulation substrate on (e.g., arranged on) the light emitting element layer; and a filling material between (e.g., arranged between) the light emitting element layer and the encapsulation substrate. The light emitting element layer further includes a spacer on (e.g., arranged on) the pixel defining film, a capping layer on (e.g., arranged on) the spacer and overlapping the emission area and the non-emission area on a plane (in plan view), and a barrier layer on (e.g., arranged on) the capping layer and overlapping the emission area and the non-emission area on a plane (in plan view). The barrier layer covers the capping layer and includes a first barrier layer and a second barrier layer on (e.g., arranged on) the first barrier layer. The spacer includes a top surface adjacent to the encapsulation substrate, a bottom surface adjacent to the base substrate, and a side surface which connects the top surface to the bottom surface, and a thickness of the barrier layer on (e.g., arranged on) the top surface of the spacer and a thickness of the barrier layer on (e.g., arranged on) the side surface of the spacer are the same.

In one or more embodiments, a cross-section of the spacer may have a reversed trapezoidal shape.

In one or more embodiments, a thickness of the second barrier layer may be larger than a thickness of the first barrier layer.

In one or more embodiments, the spacer and the filling material may be spaced and/or apart (e.g., spaced apart or separated) from each other with the capping layer and the barrier layer arranged between the spacer and the filling material.

In one or more embodiments, the second barrier layer may include a same material as the first barrier layer.

In one or more embodiments, a thickness of the first barrier layer may be about 10 Å to about 20 Å.

In one or more embodiments, a thickness of the second barrier layer may be about 10% or less of a thickness of the filling material.

In one or more embodiments, the first barrier layer may be formed through an atomic layer deposition (ALD) process, and the second barrier layer may be formed through a chemical vapor deposition (CVD) process.

According to one or more embodiments of the present disclosure, an electronic device includes a display module including a display panel, and a window module on (e.g., arranged on) the display module. The display panel includes: a base substrate including an emission area and a non-emission area which surrounds (is around) the emission area; a light emitting element layer including a pixel defining film which defines the emission area and is on (e.g., arranged on) the base substrate, a first electrode on (e.g., arranged on) the base substrate, an emission layer on (e.g., arranged on) the first electrode, and a second electrode on (e.g., arranged on) the emission layer; an encapsulation substrate on (e.g., arranged on) the light emitting element layer; and a filling material between (e.g., arranged between) the light emitting element layer and the encapsulation substrate. The light emitting element layer further includes a spacer on (e.g., arranged on) the pixel defining film, a capping layer on (e.g., arranged on) the spacer and overlapping the emission area and the non-emission area on a plane (in plan view), and a barrier layer on (e.g., arranged on) the capping layer and overlapping the emission area and the non-emission area on a plane (in plan view). The barrier layer covers the capping layer and includes a first barrier layer and a second barrier layer on (e.g., arranged on) the first barrier layer, and a density of the first barrier layer is higher than a density of the second barrier layer.

In one or more embodiments, the electronic device may further include at least one of a processor, a memory, or a power module.

In one or more embodiments, the electronic device may be at least one of a television, a monitor, an outdoor billboard, a personal computer, a notebook computer, a personal digital assistant, a vehicle instrument panel, a center fascia, a navigation unit, a room mirror display, a game console, a smartphone, a tablet computer, a smartwatch, smart glasses, a head mounted display, or a camera.

Here, for example, by incorporating a spacer with a reversed trapezoidal cross-section and layering a capping layer and dual-density barrier layers over the emission and non-emission areas, the embodiments enhance structural integrity and moisture resistance. The utilization of atomic layer deposition (ALD) for the first barrier layer ensures high density and uniform coverage, while the chemical vapor deposition (CVD) of the second barrier layer provides additional protection with desired thickness. This multi-layered encapsulation strategy, combined with spatial separation between the spacer and the filling material, contributes to improved long-term performance and durability of the display panel and the electronic device in which it is implemented.

### BRIEF DESCRIPTION OF DRAWINGS

The accompanying drawings are included to provide a further understanding of the present disclosure, and are incorporated in and constitute a part of this disclosure. The drawings illustrate embodiments of the present disclosure and, together with the description, serve to explain principles of the disclosure. Above and/or other aspects of the disclosure should become apparent and appreciated from the following description of embodiments taken in conjunction with the accompanying drawings. In the drawings:

FIG. 1 is a block diagram of an electronic device according to one or more embodiments of the present disclosure;

FIG. 2 is a schematic view illustrating various electronic devices according to one or more embodiments of the present disclosure;

FIG. 3 is an assembled perspective view of an electronic device according to one or more embodiments of the present disclosure;

FIG. 4 is an exploded perspective view of an electronic device according to one or more embodiments of the present disclosure;

FIG. 5 is a cross-sectional view of a display module according to one or more embodiments of the present disclosure;

FIG. 6 is an enlarged plan view of a display panel according to one or more embodiments of the present disclosure;

FIGS. 7A and 7B are each an enlarged cross-sectional view of a display panel according to one or more embodiments of the present disclosure;

FIGS. 8A and 8B are each an enlarged cross-sectional view of a display panel according to one or more embodiments of the present disclosure; and

FIGS. 9A-9P are each an image for confirming particle coverage according to one or more embodiments of the present disclosure.

### DETAILED DESCRIPTION

Embodiments of the present disclosure may be modified in one or more suitable forms, and one or more embodiments thereof will be illustrated in the drawings and described herein in more detail. The present disclosure should not be construed as limited to the embodiments set forth herein. Rather, these embodiments are provided so that this disclosure will be thorough and complete, and will fully convey the scope of the disclosure to those skilled in the art.

In this disclosure, it will be understood that if (e.g., when) an element (or a region, a layer, a portion, and/or the like) is referred to as being “on”, “connected to” or “coupled to” another element, it may be directly arranged on, connected to, or coupled to the other element, or one or more other elements may be arranged therebetween. In contrast, “directly on” may refer to that there are no additional intervening elements or layers between the element or layer and the other element or layer. In addition, if (e.g., when) a layer, a film, a region, a plate, and/or the like is referred to as being “under” or “below” another part, it may be “directly under” the other part, or one or more intervening layers may be present therebetween. Also, if (e.g., when) an element is referred to as being arranged “on” another element, it may be arranged under the other element.

Like reference numerals or symbols refer to like elements throughout the disclosure, and duplicative descriptions thereof may not be provided for conciseness. In the drawings, the thickness, ratio, and size of the elements may be exaggerated or reduced for effectively describing the technical contents. As used herein, the term “and/or” or “or” or “/” may include any and all combinations of one or more of the associated listed elements.

It will be understood that, although the terms “first”, “second”, and/or the like may be used herein to describe one or more suitable elements, the elements are not to be limited by these terms. These terms are only used to distinguish one element, component, region, layer, or section from another element, component, region, layer, or section. For instance, a first element, component, region, layer, or section discussed herein could be termed a second element, component, region, layer, or section without departing from the scope and teachings of the disclosure. Similarly, a second element, component, region, layer, or section could be termed a first element, component, region, layer, or section. In this disclosure, the singular expressions “a”, “an”, and “the” are intended to include the plural forms as well, unless the context clearly indicates otherwise. Further, the use of “may” when describing embodiments of the present disclosure refers to “one or more embodiments of the present disclosure.”

As used herein, the terms “below”, “under”, “on the lower side”, “above”, “over”, “on the upper side”, and/or the like may be used to describe the relationships between the elements illustrated in the drawings. These terms are relative concepts and are described on the basis of the directions indicated in the drawings.

It will be further understood that the terms “comprise(s)/include(s)/has(have)” and/or “comprising/including/having”, if (e.g., when) used in this disclosure, specify the presence of stated features, numbers, steps, operations, elements, components, or combinations thereof, but do not preclude the possibility of the presence or addition of one or more other features, numbers, steps, operations, elements, components, and/or combinations thereof. Additionally, the terms “comprise(s)/comprising,” “include(s)/including,” “has(have)/having”, or other similar terms include or support the terms “consisting of” and “consisting essentially of,” indicating the presence of stated features, numbers, steps, operations, parts, and/or components, without or essentially without the presence of other features, numbers, steps, operations, parts, components, and/or combinations thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the disclosure are described with reference to the drawings.

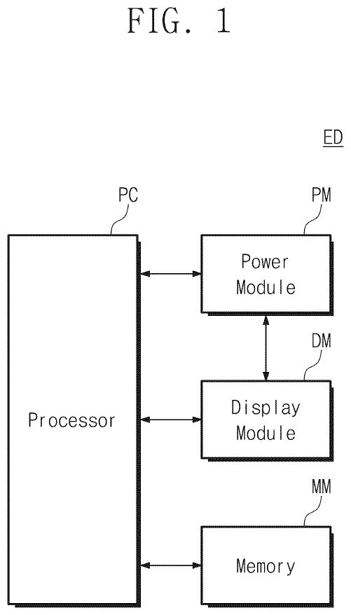

FIG. 1 is a block diagram of an electronic device according to one or more embodiments of the present disclosure.

Referring to FIG. 1, an electronic device ED according to one or more embodiments of the present disclosure may include a display module DM, a processor PC, a memory MM, and a power module PM.

The processor PC may include at least one of a central processing unit (CPU), an application processor (AP), a graphic processing unit (GPU), a communication processor (CP), an image signal processor (ISP), or a controller.

The memory MM may store data information necessary for an operation of the processor PC and/or the display module DM. When the processor PC executes an application stored in the memory MM, an image data signal and/or an input control signal may be transmitted to the display module DM, and the display module DM may process the received signal and output image information through a display screen.

The power module PM may include a power supply module such as a power adapter or a battery device, and a power conversion module which converts the power supplied by the power supply module and generates power necessary for an operation of the electronic device ED.

At least one of the foregoing components of the electronic device ED may be included in a display device according to one or more embodiments to be described later. In one or more embodiments, some of individual modules included as functional in one module may be included in the display device, and others may be provided separately from the display device. For example, the display device may include the display module DM, and the processor PC, the memory MM, and the power module PM may be provided not in the display device but in another type (kind) of device in the electronic device ED.

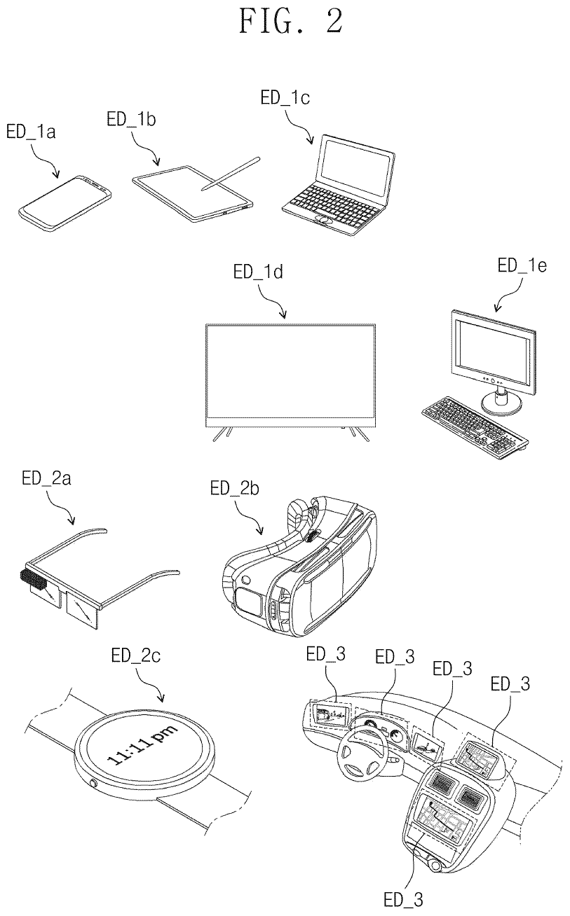

FIG. 2 is a schematic view illustrating one or more suitable electronic devices according to one or more embodiments of the present disclosure.

Referring to FIG. 2, one or more suitable electronic devices to each of which a display module according to one or more embodiments of the present disclosure is applied may include not only electronic devices for image display, such as a smartphone ED-1a, a tablet PC ED-1b, a laptop computer ED_1c, TV ED_1d, and a monitor for a desk computer ED_1e, but also wearable electronic devices such as smart glasses ED_2a, a head mounted display ED_2b, and a smartwatch ED_2c, and vehicle electronic devices ED_3 such as a vehicle instrument panel, a center fascia, a center information display (CID) arranged on a dashboard, and a room mirror display.

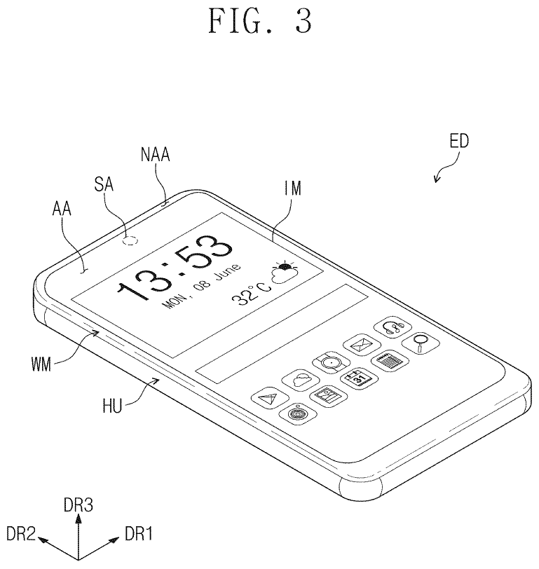

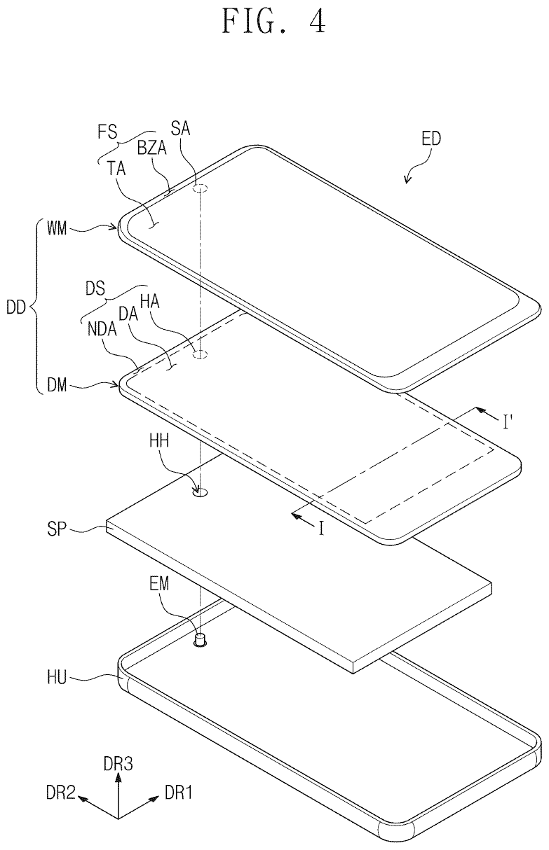

FIG. 3 is an assembled perspective view of an electronic device according to one or more embodiments of the present disclosure. FIG. 4 is an exploded perspective view of an electronic device according to one or more embodiments of the present disclosure.

An electronic device ED according to one or more embodiments may be a device that is activated in response to an electrical signal. For example, the electronic device ED may be a television, an outdoor billboard, a monitor, a mobile phone, a tablet computer, a vehicle navigation unit, a game console, or a wearable device, but embodiments of the present disclosure are not limited thereto. FIG. 3 illustrates a mobile phone as an example of the electronic device ED.

The electronic device ED according to one or more embodiments may include an active area AA and a peripheral area NAA. The active area AA of the electronic device ED may display an image IM. The image IM may include not only a dynamic image but also a still image. FIG. 3 illustrates a clock and a plurality of icons as an example of the image IM. The active area AA of the electronic device ED according to one or more embodiments may be a portion corresponding to a display area DA of a display device DD (see FIG. 4), and the peripheral area NAA may be a portion corresponding to a non-display area NDA of the display device DD. In one or more embodiments, the active area AA of the electronic device ED may be a portion corresponding to a transmission area TA of a window module WM, and the peripheral area NAA may be a portion corresponding to a bezel area BZA of the window module WM.

The electronic device ED may display the image IM in a third direction DR3 on a display surface parallel to a plane defined by a first direction axis DR1 and a second direction axis DR2. The display surface on which the image IM is displayed may correspond to a top surface (front surface) of the electronic device ED and may correspond to a top surface FS of the window module WM. In addition, the electronic device ED may have a three-dimensional shape having a certain thickness in the third direction DR3 that is a direction perpendicular to a plane defined by the first direction axis DR1 and the second direction axis DR2.

As used herein, a top surface (or front surface) and a bottom surface (or rear surface) of each of members are defined on the basis of a direction in which the image IM is displayed. The top surface and the bottom surface may oppose each other on the basis of a third direction axis DR3, and a normal direction to each of the top surface and the bottom surface may be parallel to the third direction axis DR3. Directions indicated by the first to third direction axes DR1, DR2, and DR3 are relative concepts and may be changed to other directions. Hereinafter, first to third directions are directions indicated by the first to third direction axes DR1, DR2, and DR3 and are designated by like reference numerals or symbols, respectively.

In one or more embodiments, the active area AA may have a rectangular shape parallel to a plane defined by the first direction axis DR1 and the second direction axis DR2. However, this is illustrated as an example, and the active area AA may have one or more suitable shapes and is not limited to any one particular embodiment.

The peripheral area NAA may be an area which blocks light, and an area which is arranged outside the active area AA and surrounds the active area AA. In one or more embodiments, the peripheral area NAA may be arranged on a side surface of the electronic device ED, not on a front surface thereof. In one or more embodiments, the peripheral area NAA may not be provided.

A sensing area SA may be defined to be adjacent to the active area AA of the electronic device ED according to one or more embodiments. In one or more embodiments, the sensing area SA may be arranged to be surrounded by the active area AA. In one or more embodiments, the sensing area SA may be arranged on one side of the active area AA. FIG. 3 illustrates one sensing area SA as an example, but the number of the sensing area SA is not limited thereto.

An electronic module EM may be arranged in an area overlapping the sensing area SA. The electronic module EM may receive an external input transmitted through the sensing area SA, or provide an output through the sensing area SA.

The electronic device ED according to one or more embodiments may be rigid.

The electronic device ED according to one or more embodiments may include a display module DM and the electronic module EM arranged below the display module DM. The electronic device ED according to one or more embodiments may further include the window module WM arranged on the display module DM. In addition, the electronic device ED according to one or more embodiments may further include a support member SP and/or a housing HU which are arranged below the display module DM. In the electronic device ED according to one or more embodiments illustrated in FIG. 3 and FIG. 4, the window module WM and the housing HU may be coupled to constitute an outer appearance of the electronic device ED. A through-hole HH overlapping the electronic module EM may be defined in the support member SP according to one or more embodiments.

The window module WM includes the top surface FS exposed to the outside. The transmission area TA on the top surface FS of the window module WM may be an optically transparent area. The transmission area TA may have a shape corresponding to the display area DA of the display module DM. For example, the transmission area TA overlaps an entire surface or at least a portion of the display area DA. An image displayed in the display area DA of the display module DM may be visible from the outside through the transmission area TA.

The bezel area BZA of the window module WM may be adjacent to the transmission area TA and surround the transmission area TA. The bezel area BZA may cover the non-display area NDA of the display module DM and prevent the non-display area NDA from being visible from the outside. In one or more embodiments, the sensing area SA may be defined within the transmission area TA of the window module WM. The sensing area SA of the window module WM may be defined as a sensing area SA of the electronic device ED.

In the electronic device ED according to one or more embodiments, the electronic module EM may be an electronic component which outputs or receives an optical signal. For example, in one or more embodiments, the electronic module EM may be a camera module which photographs an external image. In one or more embodiments, the electronic module EM may be a sensor module such as a proximity sensor or an infrared emission sensor.

In the electronic device ED according to one or more embodiments, the display module DM may be arranged on the electronic module EM. The display module DM may include the display area DA and the non-display area NDA adjacent to the display area DA. For example, a top surface DS of the display module DM may include the display area DA and the non-display area NDA. The top surface DS of the display module DM may be referred to as a display surface. The display area DA may be an area that is activated in response to an electrical signal.

The non-display area NDA may be adjacent to the display area DA. The non-display area NDA may surround the display area DA. A driving circuit and/or driving wiring for driving the display area DA, various signal lines and/or pads which provide an electrical signal to the display area DA, an electronic element, and/or the like may be arranged in the non-display area NDA.

In the display module DM according to one or more embodiments, a hole area HA may be defined to be adjacent to the display area DA. In one or more embodiments, the hole area HA may be arranged to be surrounded by the display area DA. In one or more embodiments, the hole area HA may be arranged on one side of the display area DA. FIG. 3 illustrates one hole area HA as an example, but the number of the hole area HA is not limited thereto. The hole area HA may correspond to the sensing area SA of the electronic device ED. The hole area HA may overlap the electronic module EM.

The support member SP arranged below the display module DM may include a cushion layer and/or a metal support layer, and/or the like. The through-hole HH may be defined in the support member SP. The through-hole HH may be defined to correspond to the hole area HA of the display module DM. The through-hole HH may be a portion corresponding to the sensing area SA of the electronic device ED.

The electronic module EM may overlap the through-hole HH. At least a portion of the electronic module EM may be inserted and arranged in the through-hole HH.

The window module WM and the housing HU may be coupled to each other to constitute an outer appearance of the electronic device ED. The window module WM and the housing HU may be coupled to define an inner space which accommodates components such as the display module DM. The display module DM, the support member SP, the electronic module EM, and/or the like may be accommodated in the inner space defined by the window module WM and the housing HU.

The housing HU may include a material having relatively high rigidity. For example, the housing HU may include a glass, a plastic, or a metal, or include a frame and/or a plate each including a combination thereof. The housing HU may be to absorb an impact applied from the outside or prevent or reduce foreign matter/moisture and/or the like from being penetrated from the outside, thereby protecting the display module DM accommodated in the housing HU.

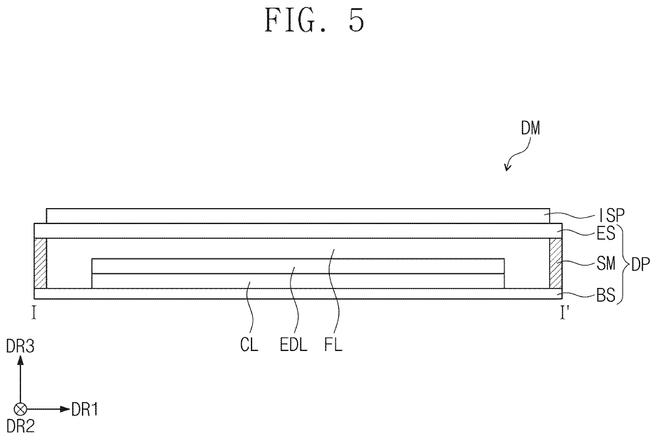

FIG. 5 is a cross-sectional view of a display module according to one or more embodiments of the present disclosure.

FIG. 5 is a cross-sectional view of a display module DM, taken along the line I-I′ illustrated in FIG. 4, according to one or more embodiments of the present disclosure.

The display module DM may include a display panel DP which generates an image. In one or more embodiments, the display module DM may further include an input sensor ISP which senses an external input. However, embodiments of the present disclosure are not limited thereto, for example, in one or more embodiments, the input sensor ISP may not be provided.

Referring to FIG. 5, in one or more embodiments, the input sensor ISP may be directly arranged on the display panel DP. In a process of manufacturing the display panel DP, the input sensor ISP may be formed on a base surface provided by the display panel DP through a substantially continuous process. The input sensor ISP and the display panel DP may be coupled into one body without a separate adhesive layer.

In one or more embodiments, the display module DM may further include an adhesive layer arranged between the input sensor ISP and the display panel DP. The input sensor ISP may be coupled to the display panel DP through the adhesive layer. For example, in one or more embodiments, the input sensor ISP may be provided as a touch panel manufactured through a separate process distinguished from the process of manufacturing the display panel DP, and the input sensor ISP may be coupled to the display panel DP through the adhesive layer arranged on a top surface of the display panel DP. The adhesive layer may include a transparent adhesive such as an optically clear adhesive film (OCA), an optically clear resin (OCR), or a pressure sensitive adhesive film (PSA). However, embodiments of the present disclosure are not necessarily limited thereto.

The stacked components and the stacking order in the display module DM illustrated in FIG. 5 are illustrative and are not limited thereto. For example, in one or more embodiments, the display module DM may further include an optical member arranged on the display panel DP.

The display panel DP may include a base substrate BS, a circuit element layer CL, a light emitting element layer EDL, an encapsulation substrate ES, and a sealant SM.

The base substrate BS may provide a base surface on which the circuit element layer CL is arranged. In one or more embodiments, the base substrate BS may be a rigid substrate. The base substrate BS may include a plastic substrate, a glass substrate, a metal substrate, an organic/inorganic composite material substrate, and/or the like. In one or more embodiments, the base substrate BS may have a multilayer structure. For example, the base substrate BS may include an inorganic layer, a synthetic resin layer, or a composite material layer.

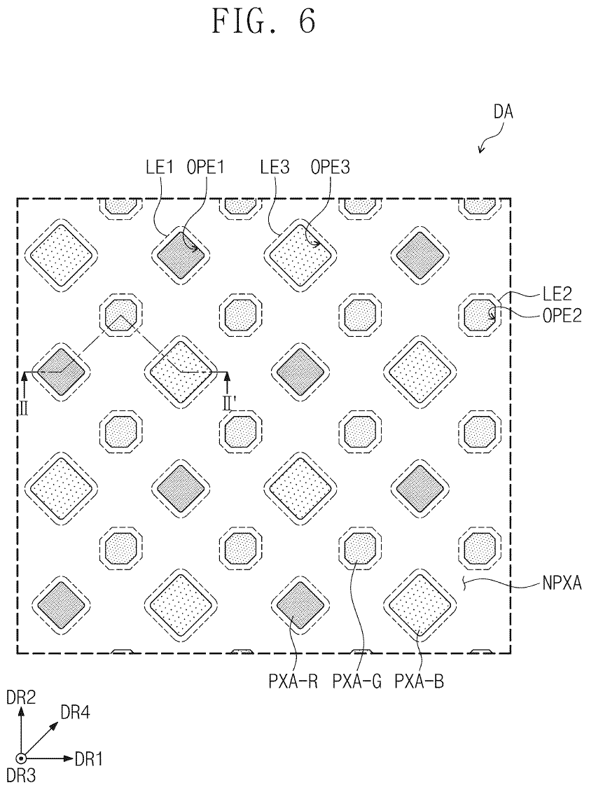

A plurality of emission areas PXA-R, PXA-G, and PXA-B (see FIG. 6) and a non-emission area NPXA (see FIG. 6) may be defined on the base substrate BS. For example, in one or more embodiments, the base substrate BS may include first to third emission areas PXA-R, PXA-G, and PXA-B (see FIG. 6) and the non-emission area NPXA (see FIG. 6) which surrounds the first to third emission areas PXA-R, PXA-G, and PXA-B (see FIG. 6). However, the kinds of the emission areas are illustrative and are not limited thereto.

The circuit element layer CL may be arranged on the base substrate BS. The circuit element layer CL may include at least one insulating layer, a semiconductor pattern, or a conductive pattern. The insulating layer, the semiconductor pattern, and the conductive pattern of the circuit element layer CL may be provided by forming the insulating layer, a semiconductor layer, and a conductive layer through coating, deposition, and/or the like, and then patterning the insulating layer, the semiconductor layer, and the conductive layer by performing a photolithography process multiple times. The insulating layer, the semiconductor pattern, and the conductive pattern included in the circuit element layer CL may provide driving elements such as a transistor, signal lines, and pads in the circuit element layer CL.

The light emitting element layer EDL may be arranged on the circuit element layer CL. The light emitting element layer EDL may include light emitting elements. The light emitting elements of the light emitting element layer EDL may be electrically connected to the driving elements of the circuit element layer CL, and generate light in response to signals provided by the driving elements and display an image.

The encapsulation substrate ES may be arranged on the light emitting element layer EDL. The encapsulation substrate ES may include a plastic substrate, a glass substrate, a metal substrate, an organic/inorganic composite material substrate, and/or the like. The encapsulation substrate ES may be spaced a certain gap from the light emitting element layer EDL in the third direction DR3.

The display module DM may further include a filling material FL which is arranged between the light emitting element layer EDL and the encapsulation substrate ES and is filled in the gap. The filling material FL may be arranged to overlap at least the display area DA. The filling material FL may include a moisture absorbent and/or a resin material. The filling material FL may be formed using an inkjet printing method, a spin coating method, a slit coating method, a jet dispensing method, or a screen printing method. However, this is illustrative, and embodiments of the present disclosure are not limited thereto.

The sealant SM may be arranged between the base substrate BS and the encapsulation substrate ES. The sealant SM may be arranged to surround the display area DA on a plane (e.g., in plan view). The sealant SM may couple the base substrate BS to the encapsulation substrate ES. The sealant SM may include an organic adhesive layer, a frit, and/or the like.

FIG. 6 is an enlarged plan view of a display panel according to one or more embodiments of the present disclosure.

FIG. 6 is an enlarged plan view of a portion of a display area DA according to one or more embodiments of the present disclosure. As an example, FIG. 6 illustrates an enlarged plane of the display area DA of the display module DM (see FIG. 4) if (e.g., when) viewed on the display surface DS (see FIG. 4).

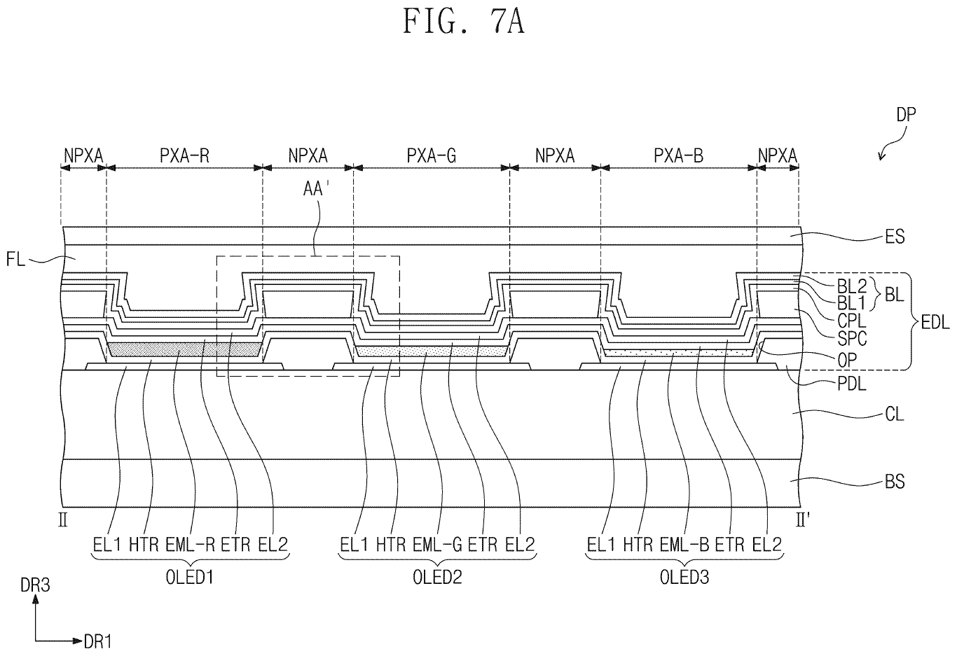

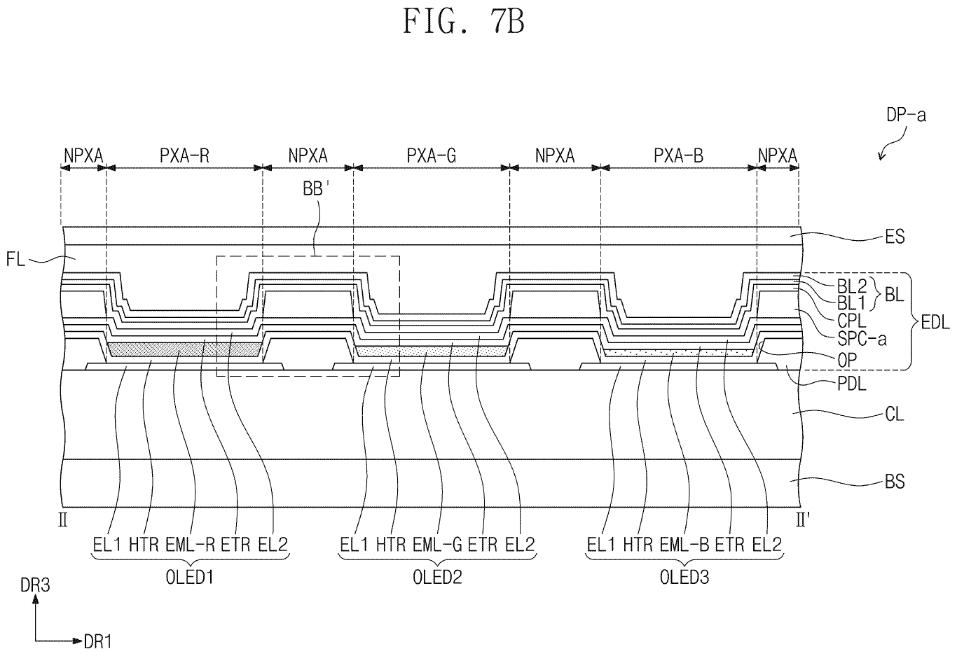

Referring to FIG. 6, the display area DA may include first to third emission areas PXA-R, PXA-G, and PXA-B and a non-emission area NPXA which surrounds the first to third emission areas PXA-R, PXA-G, and PXA-B. The first to third emission areas PXA-R, PXA-G, and PXA-B may respectively correspond to areas from which light provided from light emitting elements OLED1, OLED2, and OLED3 (see FIGS. 7A and 7B) is emitted.

Among components of the light emitting elements OLED1, OLED2, and OLED3 (see FIGS. 7A and 7B), FIG. 6 illustrates only lower electrodes LE1, LE2, and LE3 corresponding to second electrodes EL2 (see FIGS. 7A and 7B) for convenience of description. The first to third emission areas PXA-R, PXA-G, and PXA-B may be divided according to colors of light emitted toward the outside of a display panel DP.

The first to third emission areas PXA-R, PXA-G, and PXA-B may respectively provide light of first to third colors different from one another. For example, in one or more embodiments, the light of the first color may be red light, the light of the second color may be green light, and the light of the third color may be blue light. However, examples of the light of the first to third colors are not necessarily limited to the foregoing examples.

Each of the first to third emission areas PXA-R, PXA-G, and PXA-B may be defined as an area which is of a top surface of a corresponding one of the lower electrodes LE1, LE2, and LE3 and is exposed by a corresponding one of emission opening portions OPE1, OPE2, and OPE3. The emission opening portions OPE1, OPE2, and OPE3 may be defined by a pixel defining film PDL (see FIGS. 7A and 7B) which covers a portion of the lower electrodes LE1, LE2, and LE3, which will be described later in more detail. The emission opening portions OPE1, OPE2, and OPE3 may respectively correspond to opening portions OP (see FIGS. 7A and 7B) which will be described later.

For example, the first emission area PXA-R may be defined as an area which is of a top surface of a first lower electrode LE1 and is exposed by a first emission opening portion OPE1. In addition, the second emission area PXA-G may be defined as an area which is of a top surface of a second lower electrode LE2 and is exposed by a second emission opening portion OPE2. In addition, the third emission area PXA-B may be defined as an area which is of a top surface of a third lower electrode LE3 and is exposed by a third emission opening portion OPE3.

The non-emission area NPXA may set a boundary between the first to third emission areas PXA-R, PXA-G, and PXA-B and prevent or reduce color mixture between the first to third emission areas PXA-R, PXA-G, and PXA-B.

For example, referring to FIG. 6, a plurality of first emission areas PXA-R and a plurality of third emission areas PXA-B may be alternated in the first direction DR1 to constitute a “first group”. In addition, a plurality of second emission areas PXA-G may be aligned in the first direction DR1 to constitute a “second group”. Each of the “first group” and the “second group” may be provided in plurality, and the “first groups” and the “second groups” may be alternated in the second direction DR2.

One second emission area PXA-G may be arranged to be spaced and/or apart (e.g., spaced apart or separated) from one first emission area PXA-R or one third emission area PXA-B in a fourth direction DR4. The fourth direction DR4 may be defined as a direction oriented between the first direction DR1 and the second direction DR2 on a plane defined by the first direction DR1 and the second direction DR2.

As illustrated in FIG. 6, in one or more embodiments, the first to third emission areas PXA-R, PXA-G, and PXA-B may have a PenTile (PENTILE®) arrangement shape. However, the arrangement shape of the first to third emission areas PXA-R, PXA-G, and PXA-B illustrated in FIG. 6 is an example and is not limited thereto, and the first to third emission areas PXA-R, PXA-G, and PXA-B may be arranged in one or more suitable shapes. For example, in one or more embodiments, the first to third emission areas PXA-R, PXA-G, and PXA-B may have a stripe arrangement shape or a diamond (Diamond Pixel™) arrangement shape. PENTILE® is a duly registered trademark of Samsung Display Co., Ltd. Diamond Pixel™ is a trademark of Samsung Display Co., Ltd.

The first to third emission areas PXA-R, PXA-G, and PXA-B may each have a suitable shape on a plane (e.g., in plan view). For example, the first to third emission areas PXA-R, PXA-G, and PXA-B may each have a shape such as a polygonal shape, a circular shape, or an oval shape. As an example, FIG. 6 illustrates the first emission areas PXA-R and the third emission areas PXA-B each having a rectangular (or rhombus) shape on a plane, and the second emission area PXA-G having an octagonal shape on a plane.

In one or more embodiments, the first to third emission areas PXA-R, PXA-G, and PXA-B may have a same shape on a plane, or at least some thereof may have different shapes on a plane. As an example, FIG. 6 illustrates the first emission areas PXA-R and the third emission areas PXA-B which have the same shape, and the second emission area PXA-G which has a different shape from each of the first emission areas PXA-R and the third emission areas PXA-B on a plane.

In one or more embodiments, at least some of the first to third emission areas PXA-R, PXA-G, and PXA-B may have different surface areas on a plane. For example, in one or more embodiments, a surface area of the first emission area PXA-R which emits the red light may be larger than a surface area of the second emission area PXA-G which emits the green light, and be smaller than a surface area of the third emission area PXA-B which emits the blue light. However, a large-small relationship between the surface areas of the first to third emission areas PXA-R, PXA-G, and PXA-B according to the colors of the emitted light is not limited thereto, and may vary according to the design of the display module DM (see FIG. 4). For example, in one or more embodiments, the first to third emission areas PXA-R, PXA-G, and PXA-B may have a same surface area in size on a plane.

The shapes, the surface areas, and the arrangements of the first to third emission areas PXA-R, PXA-G, and PXA-B of the display module DM (see FIG. 4) according to the present disclosure on a plane may be variously designed according to the color of the emitted light or the size or configuration of the display module DM (see FIG. 4), and are not limited to an embodiment illustrated in FIG. 6.

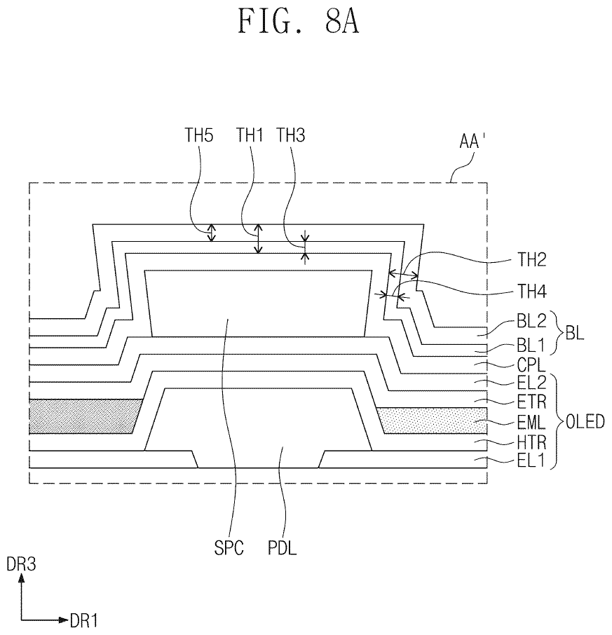

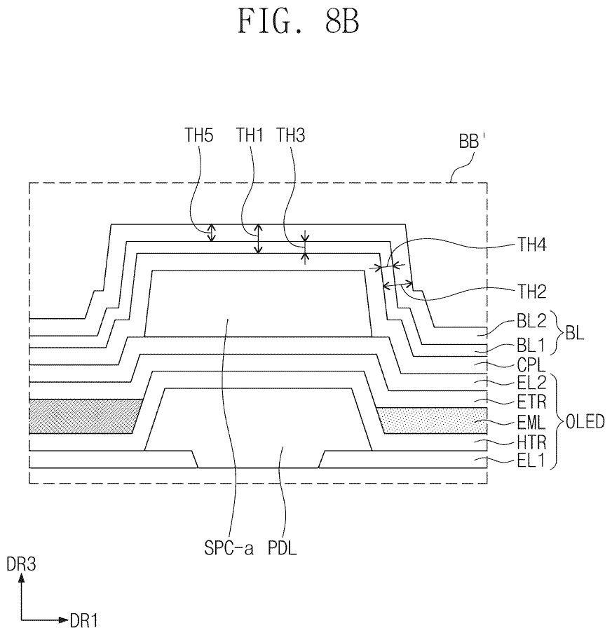

FIG. 7A and FIG. 7B are each an enlarged cross-sectional view of a display panel according to one or more embodiments of the present disclosure. FIG. 8A and FIG. 8B are each an enlarged cross-sectional view of a display panel according to one or more embodiments of the disclosure.

For example, FIG. 7A is a cross-sectional view of a display panel DP, taken along the line II-II′ illustrated in FIG. 6, according to one or more embodiments of the present disclosure. FIG. 7B is a cross-sectional view of a display panel DP-a, corresponding to the line II-II′ illustrated in FIG. 6, according to one or more embodiments of the present disclosure. FIG. 8A is an enlarged cross-sectional view of the area AA in FIG. 7A according to one or more embodiments. FIG. 8B is an enlarged cross-sectional view of the area BB′ in FIG. 7B according to one or more embodiments.

Referring to FIG. 7A, the display panel DP may include a base substrate BS, a circuit element layer CL arranged on the base substrate BS, a light emitting element layer EDL arranged on the circuit element layer CL, an encapsulation substrate ES arranged on the light emitting element layer EDL, and a filling material FL arranged between the light emitting element layer EDL and the encapsulation substrate ES. The descriptions provided above with reference to FIG. 5 may apply to the base substrate BS, the circuit element layer CL, the filling material FL, and the encapsulation substrate ES.

The light emitting element layer EDL may include a pixel defining film PDL, light emitting elements OLED1, OLED2, and OLED3, a spacer SPC, and a capping layer CPL.

The light emitting elements OLED1, OLED2, and OLED3 may be arranged on the circuit element layer CL. The light emitting elements OLED1, OLED2, and OLED3 may each include a first electrode EL1 arranged on the circuit element layer CL, a hole transport region HTR arranged on the first electrode EL1, an emission layer EML-R, EML-G, or EML-B arranged on the hole transport region HTR, an electron transport region ETR arranged on the emission layer EML-R, EML-G, or EML-B, and a second electrode EL2 arranged on the electron transport region ETR. The second electrode EL2 may correspond to the lower electrodes LE1, LE2, and LE3 illustrated in FIG. 6.

An embodiment is illustrated in which the respective emission layers EML-R, EML-G, and EML-B of the light emitting elements OLED1, OLED2, and OLED3 are respectively arranged in opening portions OP defined in the pixel defining films PDL, and the hole transport region HTR, the electron transport region ETR, and the second electrode EL2 are each provided as a common layer over the entirety of the light emitting elements OLED1, OLED2, and OLED3. Each of the hole transport region HTR, the electron transport region ETR, and the second electrode EL2 may be formed as a common layer by using an open mask. However, embodiments of the present disclosure are not limited thereto, and in one or more embodiments unlike an embodiment illustrated in FIG. 7A, the hole transport region HTR and the electron transport region ETR may be provided by being patterned inside the opening portions OP defined in the pixel defining films PDL. For example, in one or more embodiments, the hole transport region HTR, the respective emission layers EML-R, EML-G, and EML-B, the electron transport region ETR, and/or the like of the light emitting elements OLED1, OLED2, and OLED3 may be provided by being patterned through thermal evaporation using a mask.

The display panel DP may include a non-emission area NPXA and emission areas PXA-R, PXA-G, and PXA-B. The emission areas PXA-R, PXA-G, and PXA-B may be respectively areas from which light generated from the light emitting elements OLED1, OLED2, and OLED3 is emitted. The emission areas PXA-R, PXA-G, and PXA-B may be spaced and/or apart (e.g., spaced apart or separated) from one another on a plane (e.g., in plan view).

The emission areas PXA-R, PXA-G, and PXA-B may be areas divided by the pixel defining film PDL. For example, the pixel defining film PDL may define the emission areas PXA-R, PXA-G, and PXA-B. The non-emission area NPXA may be an area between neighboring emission areas of the emission areas PXA-R, PXA-G, and PXA-B and be an area corresponding to the pixel defining film PDL. In the present disclosure, each of the emission areas PXA-R, PXA-G, and PXA-B may correspond to a pixel. The respective emission layers EML-R, EML-G, and EML-B of the light emitting elements OLED1, OLED2, and OLED3 may be divided by being arranged in the opening portions OP defined in the pixel defining film PDL.

The emission areas PXA-R, PXA-G, and PXA-B may be divided into a plurality of groups according to colors of light generated from the light emitting elements OLED1, OLED2, and OLED3. For example, the display panel DP according to one or more embodiments may include a red emission area PXA-R, a green emission area PXA-G, and a blue emission area PXA-B which are separated from one another. The plurality of light emitting elements OLED1, OLED2, and OLED3 may be to emit light in different wavelength regions. For example, the display panel DP according to one or more embodiments may include a first light emitting element OLED1 which emits red light, a second light emitting element OLED2 which emits green light, and a third light emitting element OLED3 which emits blue light. For example, the red emission area PXA-R, the green emission area PXA-G, and the blue emission area PXA-B of the display panel DP may respectively correspond to areas in which the first light emitting element OLED1, the second light emitting element OLED2, and the third light emitting element OLED3 are arranged.

The spacer SPC may be arranged on the pixel defining film PDL. The spacer SPC may be a component for maintaining a distance between the encapsulation substrate ES arranged above the spacer SPC and components below the encapsulation substrate ES. In addition, the spacer SPC may minimize or reduce a pressure applied to the light emitting elements OLED1, OLED2, and OLED3 in a process of bonding the base substrate BS and the encapsulation substrate ES.

The spacer SPC may overlap the pixel defining film PDL. The spacer SPC may be arranged on a portion of the pixel defining film PDL. For example, a portion of the pixel defining film PDL may overlap the spacer SPC, but another portion thereof may not overlap the spacer SPC. The spacer SPC may be arranged in a regular or irregular distribution on the pixel defining film PDL. For example, in one or more embodiments, the spacer SPC may be arranged between the plurality of emission areas PXA-R, PXA-G, and PXA-B. For example, the spacer SPC may be between the first emission area PXA-R and the second emission area PXA-G, between the first emission area PXA-R and the third emission area PXA-B, and between the second emission area PXA-G and the third emission area PXA-B. However, the arrangement of the spacer SPC on a plane (e.g., in plan view) is not limited thereto.

The capping layer CPL may be arranged on the spacer SPC. The capping layer CPL may be directly arranged on the spacer SPC and cover the spacer SPC. The capping layer CPL may overlap the emission areas PXA-R, PXA-G, and PXA-B and the non-emission area NPXA on a plane (e.g., in plan view). The capping layer CPL may be provided as a common layer over the entirety of the light emitting elements OLED1, OLED2, and OLED3. In the emission areas PXA-R, PXA-G, and PXA-B, the capping layer CPL may be arranged on the second electrode EL2 and be in contact with the second electrode EL2. The capping layer CPL may include an organic material. The capping layer CPL may be a component for protecting the second electrode EL2 from a follow-up process, for example, an atomic layer deposition (ALD) process or a chemical vapor deposition (CVD) process, and improving luminance efficiency of the light emitting elements OLED.

The light emitting element layer EDL further includes a barrier layer BL arranged on the capping layer CPL. The barrier layer BL may overlap the emission areas PXA-R, PXA-G, and PXA-B and the non-emission area NPXA on a plane (e.g., in plan view). The barrier layer BL may cover the capping layer CPL. The spacer SPC and the filling material FL may be spaced and/or apart (e.g., spaced apart or separated) from each other with the barrier layer BL therebetween.

The barrier layer BL may include an inorganic material. Accordingly, the barrier layer BL may prevent or reduce oxygen, moisture, and/or the like from being penetrated from the outside. The barrier layer BL may be a component for preventing or reducing a contact between the filling material FL and the spacer SPC to reduce reaction possibility. When the reaction possibility between the filling material FL and the spacer SPC is reduced, defects such as dark spot(s) and blur appearing in the active area AA (see FIG. 3) may be reduced. Accordingly, the display panel DP according to one or more embodiments and the electronic device ED (see FIG. 1) including the display panel DP may be improved in display quality and reliability thereof may be improved. In addition, when the reaction possibility between the filling material FL and the spacer SPC is reduced, even a material likely to react with the spacer SPC may be applied to the filling material FL, and thus limitation of materials which may be applied to the filling material FL may be reduced.

The barrier layer BL may also be a component for reducing reaction possibility between the filling material FL and the capping layer CPL. When the reaction possibility between the filling material FL and the capping layer CPL is reduced, even a material likely to react with the filling material FL may be used as a material of the capping layer CPL, and thus limitation of materials which may be used as the material of the capping layer CPL may be reduced.

Referring to FIG. 7A and FIG. 8A, the barrier layer BL may include a first barrier layer BL1 and a second barrier layer BL2 arranged on the first barrier layer BL1. A density of the first barrier layer BL1 may be higher than a density of the second barrier layer BL2. As described later, this is because the first barrier layer BL1 may be formed through an atomic layer deposition (ALD) process and the second barrier layer BL2 may be formed through a chemical vapor deposition (CVD) process. A thickness TH5 of the second barrier layer BL2 may be larger than a thickness TH3 or TH4 of the first barrier layer BL1. As described later, this is because the first barrier layer BL1 may serve as a seed layer of the second barrier layer BL2 and the second barrier layer BL2 may serve to cover particle(s). That is, for example, the first barrier layer (BL1) formed by ALD has a higher density because ALD builds the film atom-by-atom in a controlled manner, resulting in a compact and uniform layer. This makes it desired as the seed layer for the second barrier layer (BL2), which is thicker but less dense due to the nature of CVD, which deposits material more quickly and less compact.

The first barrier layer BL1 and the second barrier layer BL2 may each include an inorganic material. In one or more embodiments, the first barrier layer BL1 and the second barrier layer BL2 may each include a silane-based material (e.g., a material derived from a silane-based compound as a precursor). For example, the first barrier layer BL1 and the second barrier layer BL2 may each include silicon oxide, silicon nitride, or silicon oxynitride. The second barrier layer BL2 may include a same material as the first barrier layer BL1. Here, with regard to the same material, compounds having the same chemical formula and maintaining the same atomic arrangement and bonding state may be defined as the same material. Although different in physical state (including density), compounds may correspond to the same material as long as having the same chemical properties. Thus, the second barrier layer BL2 may be formed using a same precursor as the first barrier layer BL1. A silane-based compound may be used as the precursor.

Referring to FIG. 8A, the thickness TH3 or TH4 of the first barrier layer BL1 may be about 10 Å or more. For example, in one or more embodiments, the thickness TH3 or TH4 of the first barrier layer BL1 may be about 10 Å to about 20 Å. However, the thickness of the first barrier layer BL1 is not limited to being about 20 Å or less. When the thickness of the first barrier layer BL1 is about 10 Å or more, the first barrier layer BL1 may serve as a seed layer which may induce the formation of the second barrier layer BL2.

The thickness TH5 of the second barrier layer BL2 may be larger than the thickness TH3 or TH4 of the first barrier layer BL1. The thickness TH5 of the second barrier layer BL2 may be about 10% or less of a thickness of the filling material FL. The thickness of the filling material FL may be about 20 micrometers (μm) or less. For example, in one or more embodiments, the thickness of the filling material FL may be about 8 μm to about 10 μm. The thickness of the filling material FL may be defined as a length in which the filling material FL is filled in the third direction DR3 in the non-emission area NPXA in which the spacer SPC is arranged.

The thickness TH5 of the second barrier layer BL2 may be about 10 kA to about 20 kA. Within the foregoing thickness range of the second barrier layer BL2, the second barrier layer BL2 may cover the particle(s) and prevent or reduce generation of dark spot(s) caused by the particle(s). The larger the thickness TH5 of the second barrier layer BL2 is, the more the second barrier layer BL2 may be effective in covering the particle(s). However, if (e.g., when) the thickness TH5 of the second barrier layer BL2 is increased, process efficiency may be decreased. The foregoing numerical range is an example, and the thickness TH5 of the second barrier layer BL2 may be selected as appropriate or suitable according to a state in which the particle(s) are managed, or a purpose of using the display panel.

The spacer SPC may include a top surface adjacent to the encapsulation substrate ES, a bottom surface adjacent to the base substrate BS, and a side surface which connects the top surface to the bottom surface. A thickness TH1 of the barrier layer BL arranged on the top surface of the spacer SPC and a thickness TH2 of the barrier layer BL arranged on the side surface of the spacer SPC may be the same. In addition, the thickness TH3 of the first barrier layer BL1 arranged on the top surface of the spacer SPC and the thickness TH4 of the first barrier layer BL1 arranged on the side surface of the spacer SPC may be the same. As described later, this is because the first barrier layer BL1 may be formed through the atomic layer deposition (ALD) process, which will be described later in more detail. Here, the thicknesses being the same may refer to a case in which thicknesses may be in a range in which the thicknesses may be determined to be the same in consideration of fabrication errors.

The first barrier layer BL1 may be formed through the atomic layer deposition (ALD) process, and the second barrier layer BL2 may be formed through the chemical vapor deposition (CVD) process. The first barrier layer BL1 formed through the atomic layer deposition (ALD) process may serve as a seed layer which may induce the formation of the second barrier layer BL2. In addition, the first barrier layer BL1 formed through the atomic layer deposition (ALD) process may guide the second barrier layer BL2 to be deposited in a substantially uniform thickness. Thus, the second barrier layer BL2 may be prevented from being formed in a smaller thickness at a specific position. For example, the second barrier layer BL2 may be prevented from being formed in a smaller thickness on the side surface of the spacer SPC than on the top surface of the spacer SPC. Moreover, even when a cross-section of the spacer SPC has a reversed trapezoidal shape, the second barrier layer BL2 may be prevented from being formed in a smaller thickness on the side surface of the spacer SPC than on the top surface of the spacer SPC. As used herein, “cross-section of the spacer SPC has a reversed trapezoidal shape” refers to the cross-section of the spacer SPC having a trapezoidal shape with a longer parallel side adjacent to the encapsulation substrate ES and a shorter parallel side adjacent to the capping layer CPL.

According to the present disclosure, if (e.g., when) the first barrier layer BL1 is formed through the atomic layer deposition (ALD) process and the second barrier layer BL2 is be formed through the chemical vapor deposition (CVD) process, the thickness TH3 of the first barrier layer BL1 arranged on the top surface of the spacer SPC and the thickness TH4 of the first barrier layer BL1 arranged on the side surface of the spacer SPC may be the same. In addition, as the first barrier layer BL1 formed through the atomic layer deposition (ALD) process serves as a seed layer, the second barrier layer BL2 may be formed in a substantially uniform thickness. Thus, the thickness TH1 of the barrier layer BL arranged on the top surface of the spacer SPC and the thickness TH2 of the barrier layer BL arranged on the side surface of the spacer SPC may be the same.

In addition, compared to if (e.g., when) the entirety of the barrier layer BL is formed through the atomic layer deposition (ALD) process, a thickness of an atomic layer deposition (ALD) layer necessary to obtain the equivalent effect of reducing the reaction possibility between the spacer SPC and the filling material FL may be smaller in an embodiment in which the first barrier layer BL1 is formed through the atomic layer deposition (ALD) process and the second barrier layer BL2 is formed through the chemical vapor deposition (CVD) process. Thus, according to the present disclosure, even if (e.g., when) the thinner ALD layer is formed compared to when the entirety of the barrier layer BL is formed through the atomic layer deposition (ALD) process, the reaction possibility between the spacer SPC and the filling material FL may be reduced to have an effect in which a tact is reduced. Furthermore, the second barrier layer BL2 formed through the chemical vapor deposition (CVD) process may cover the particle(s) and reduce generation of dark spot(s) caused by the particle(s).

Barrier properties of the barrier layer BL according to one or more embodiments of the present disclosure were evaluated. Table 1 shows results of evaluating the barrier properties of Embodiment 1 and Comparative Example 1. A barrier layer BL according to Embodiment 1 includes a first barrier layer BL1 formed through the atomic layer deposition (ALD) process and a second barrier layer BL2 formed through the chemical vapor deposition (CVD) process. A barrier layer according to Comparative Example 1 has the same thickness as the second barrier layer BL2 according to Embodiment 1, and the entirety of the barrier layer was formed through the chemical vapor deposition (CVD) process.

For example, the barrier layer BL according to Embodiment 1 includes the first barrier layer BL1, which includes a silicon nitride formed through the atomic layer deposition (ALD) process and having a thickness of about 15 Å and serves as a seed layer, and the second barrier layer BL2 which includes a silicon nitride formed on the first barrier layer BL1 through the chemical vapor deposition (CVD) process and having a thickness of about 10,000 Å. The barrier layer according to Comparative Example 1 includes a silicon nitride formed through the chemical vapor deposition (CVD) process and having a thickness of about 10,000 Å.

A water vapor transmission rates (WVTR) was measured to confirm the barrier properties according to whether the seed layer is included or not, and a refractive index, an absorption coefficient, and a transmittance were measured to confirm changes in optical properties according to whether the seed layer is included or not. The refractive index is a value measured for light having a wavelength of about 550 nm. The absorption coefficient is a value measured for light having a wavelength of about 460 nm. The transmittance is a value measured for light having a wavelength of about 500 nm.

TABLE 1

| | | Comparative |
|---|---|---|
| | Embodiment 1 | Example 1 |
| Thickness of layer | 10,000 | 10,000 |
| formed through CVD (Å) | | |
| WVTR (g/m² · day) | ≤5.0 × 10⁻⁵ | 3.0 × 10⁻⁴ |
| Refractive index | 1.86 | 1.87 |
| Absorption coefficient | <0.002 | 0.002 |
| Transmittance (%) | 98 | 96 |

Referring to Table 1, it may be confirmed that the barrier layer BL according to Embodiment 1 including the first barrier layer BL1 formed through the ALD process exhibits the improved barrier properties compared to the barrier layer according to Comparative Example 1. For example, the barrier layer BL according to Embodiment 1 has a lower water vapor transmission rate (WVTR) than the barrier layer according to Comparative Example 1. It may be further confirmed that the barrier layer BL according to Embodiment 1 and the barrier layer according to Comparative Example 1 have the similar refractive indexes, absorption coefficients, and transmittances. Thus, compared to the barrier layer according to Comparative Example 1 not including the seed layer, the barrier layer BL according to Embodiment 1 including the seed layer may have the improved barrier properties with the optical properties maintained. Because the capping layer CPL is not uniformly formed in a same thickness on the top surface and the side surfaces of the spacer SPC, the filling material FL penetrates the capping layer CPL and reacts with the spacer SPC to easily form dark spots, blur, and/or the like when the barrier layer BL is not included unlike the present disclosure. Particularly if (e.g., when) the cross-section of the spacer SPC has a reversed trapezoidal shape, the capping layer CPL is not uniformly formed in a same thickness on the top surface and the side surfaces of the spacer SPC, and thus the filling material FL penetrates the capping layer CPL and reacts with the spacer SPC to easily form dark spots, blur, and/or the like. However, when the barrier layer BL is included as disclosed in the present disclosure, the barrier layer BL may prevent the contact between the filling material FL and the spacer SPC, thereby preventing the formation of dark spots, blur, and/or the like occurring if (e.g., when) the cross-section of the spacer SPC has a reversed trapezoidal shape. Thus, limitation of the shape of the spacer SPC, which may be applied if (e.g., when) the barrier layer BL is included, may be reduced. FIG. 7A illustrates an example in which the cross-section of the spacer SPC has a reversed trapezoidal shape. However, embodiments of the present disclosure are not limited thereto, for example, the spacer SPC may have any suitable shapes. FIG. 7B illustrates an example in which a cross-section of a spacer SPC-a has a trapezoidal shape.

FIG. 7B differs from FIG. 7A only in that the spacer SPC-a having the cross-section having a trapezoidal shape is illustrated instead of the spacer SPC having the cross-section having a reversed trapezoidal shape. As described above, the spacer SPC may have one or more suitable shapes, and as an example thereof, FIG. 7B illustrates the spacer SPC-a having the cross-section having a trapezoidal shape. Thus, except that the cross-section of the spacer SPC-a has a trapezoidal shape, the same descriptions provided above with reference to FIG. 7A may apply to FIG. 7B. Likewise, FIG. 8B differs from FIG. 8A only in that a spacer SPC-a having a cross-section having a trapezoidal shape is illustrated instead of the spacer SPC having the cross-section having a reversed trapezoidal shape. Thus, except that the cross-section of the spacer SPC-a has a trapezoidal shape, the same descriptions provided above with reference to FIG. 8A may apply to FIG. 8B.

In one or more embodiments, FIG. 7A illustrates the spacer SPC having a size and a thickness similar to those of the pixel defining film PDL. However, embodiments of the present disclosure are not limited thereto, and the size and the thickness of the spacer SPD are not limited.

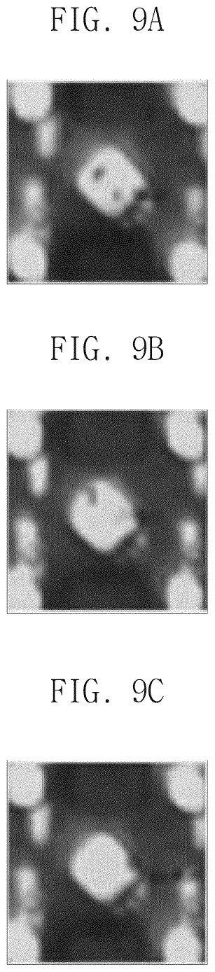

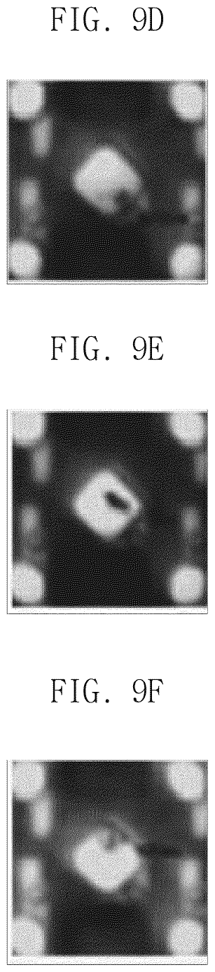

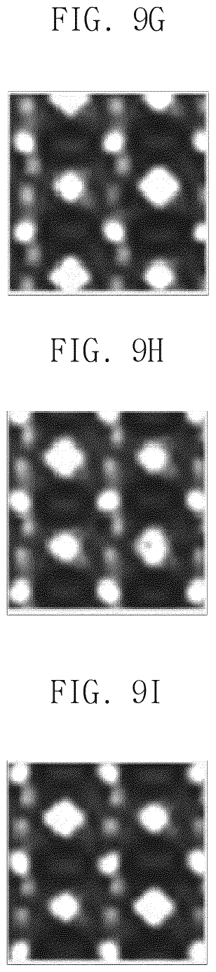

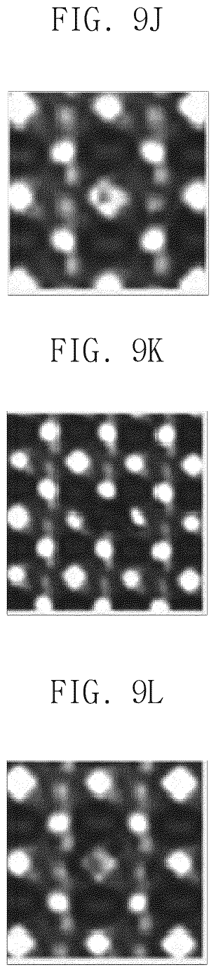

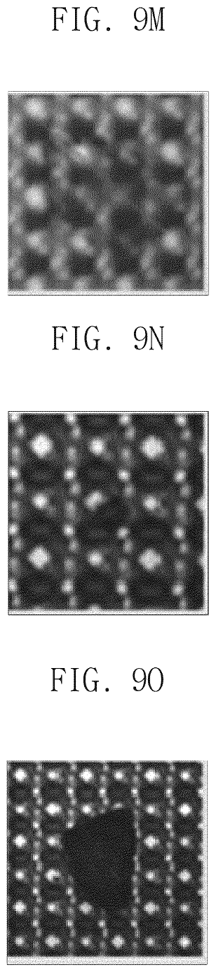

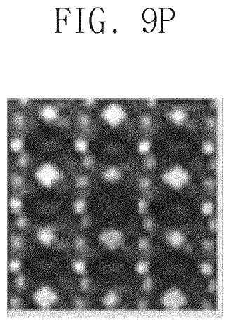

FIGS. 9A to 9P are each an image for confirming particle coverage according to one or more embodiments of the present disclosure.

Particle coverage properties of a barrier layer BL according to one or more embodiments of the disclosure were evaluated. Table 2 shows results of confirming particle coverage of an embodiment including a first barrier layer BL1 formed through an atomic layer deposition (ALD) process and having a thickness of about 10 Å, and a 10 second barrier layer BL2 formed through a chemical vapor deposition (CVD) process and having a thickness of about 18 kA. The number (occupancy) of particles corresponding to each size category and an average size as measured are set forth. FIGS. 9A to 9P are each an image for confirming particle coverage effects according to an embodiment in Table 2.

TABLE 2

| | | | | | | | Dark spot-causing |
|---|---|---|---|---|---|---|---|
| | | | | | | | particles in |
| | | | | | | | lighting defect |
| Position | Particles in normal lighting position | | | | | | position |
| Size | ≤2 | 2-4 | 4-6 | 6-8 | 8-10 | >10 | >10 |
| category | | | | | | | |
| (μm) | | | | | | | |
| Number | 6 | 5 | 8 | 3 | 2 | 6 | 7 |
| (occupancy) | (20%) | (17%) | (27%) | (10%) | (7%) | (20%) | |
| Average | 1.9 ± | 2.7 ± | 4.3 ± | 6.5 ± | 8.6 | 19.1 ± | >11.6 |
| size (μm) | 0.2 | 0.5 | 0.9 | 1.3 | | 7.8 | |

Referring to Table 2 and FIGS. 9A to 9P, the particles having a size of about 10 μm or less were covered and did not cause dark spots. However, some of the particles having a size of more than about 10 μm caused dark spots. For example, FIGS. 9A and 9B are images on which the particles having a size of about 2 μm or less in the normal lighting position were confirmed. FIGS. 9C and 9D are images on which the particles having a size of more about 2 μm and about 4 μm or less in the normal lighting position were confirmed. FIGS. 9E and 9F are images on which the particles having a size of more about 4 μm and about 6 μm or less in the normal lighting position were confirmed. FIGS. 9G and 9H are images on which the particles having a size of more about 6 μm and about 8 μm or less in the normal lighting position were confirmed. FIGS. 91 and 9J are images on which the particles having a size of more about 8 μm and about 10 μm or less in the normal lighting position were confirmed. FIGS. 9K and 9L are images on which the particles having a size of more about 10 μm in the normal lighting position were confirmed. FIGS. 9M to 9P are images on which the dark spot-causing particles in the lighting defect position were confirmed.

As described above, the display panel and the electronic device according to the present disclosure may include the barrier layer arranged between the filling material and the capping layer, thereby reducing the dark spots, the blur, and/or the like which may be generated by the reaction between the spacer and the filling material. Accordingly, the reliability may be improved.

Moreover, the display panel and the electronic device according to the present disclosure may include the barrier layer arranged between the filling material and the capping layer, thereby reducing the limitation of a material available as the material of the filling material or the limitation of the shape of the spacer.

For example, by mitigating the interaction between the filling material and the spacer through the inclusion of the barrier layer, the present disclosure enables broader material selection and geometric design flexibility. In comparable configurations lacking such a barrier, the choice of filling materials is often constrained by their chemical compatibility with the spacer, and the spacer shape should be carefully controlled to avoid uneven coverage and defect formation. However, the barrier layer disclosed herein acts as a protective interface, allowing the utilization of diverse spacer shapes—including trapezoidal and reversed trapezoidal profiles—and a wider range of filling materials without compromising display performance. This not only simplifies manufacturing tolerances but also supports the development of thinner, more compact, and more reliable electronic devices with high-resolution display panels.

Also, in the context of the present disclosure and unless otherwise defined, “on a plane” or “a plan view” is an orthographic projection of a three-dimensional object from the position of a horizontal plane intersecting the object. That is, it is a top-down view, showing the layout and spatial relationships of various elements within the object or structure. “On a plane” or “a plan view” based on a third direction DR3 (e.g., a thickness direction) refers to a top-down view of the object, as if looking directly down onto the surface from above. Accordingly, “a cross-section” refers to a side view of the object, as if looking directly from a first direction DR1 or a second direction DR2. In this context, the third direction DR3 is perpendicular or normal to the horizontal plane defined by the first direction DR1 and the second direction DR2.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or ±5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

In the context of the present application and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

The light emitting element, the display device, the display panel, the electronic device/apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In the present disclosure, each suitable feature of the various embodiments of the disclosure may be combined or combined with each other, partially or entirely, and may be technically interlocked and operated in various suitable ways, and each embodiment may be implemented independently of each other or in conjunction with each other in any suitable manner unless otherwise stated or implied.

In the above, description has been made with reference to one or more embodiments of the disclosure, but those skilled or of ordinary skill in the art may understand that one or more suitable modifications and changes may be made to the disclosure insofar as such modifications and changes do not depart from the spirit and technical scope of the disclosure set forth in the appended claims. Therefore, the technical scope of the present disclosure is not to be limited to the content stated in the detailed description of the disclosure, but should be determined by the claims and equivalents thereof.

What is claimed is:

1. A display panel, comprising:
a base substrate comprising
an emission area, and
a non-emission area around the emission area;
a light emitting element layer comprising
a pixel defining film configured to define the emission area and on the base substrate,
a first electrode on the base substrate, an emission layer on the first electrode, and
a second electrode on the emission layer;
an encapsulation substrate on the light emitting element layer; and
a filling material between the light emitting element layer and the encapsulation substrate,
wherein the light emitting element layer further comprises
a spacer on the pixel defining film,
a capping layer on the spacer and overlapping the emission area and the non-emission area in plan view, and
a barrier layer on the capping layer and overlapping the emission area and the non-emission area in plan view,
wherein the barrier layer covers the capping layer and comprises a first barrier layer and a second barrier layer on the first barrier layer, and
wherein a density of the first barrier layer is higher than a density of the second barrier layer.

2. The display panel of claim 1, wherein a cross-section of the spacer has a reversed trapezoidal shape.

3. The display panel of claim 1, wherein a thickness of the second barrier layer is larger than a thickness of the first barrier layer.

4. The display panel of claim 1, wherein the spacer and the filling material are spaced from each other with the capping layer and the barrier layer between the spacer and the filling material.

5. The display panel of claim 1, wherein the second barrier layer comprises a same material as the first barrier layer.

6. The display panel of claim 1, wherein a thickness of the first barrier layer is 10 Å to 20 Å.

7. The display panel of claim 1, wherein a thickness of the second barrier layer is 10% or less of a thickness of the filling material.

8. The display panel of claim 1, wherein the spacer comprises a top surface adjacent to the encapsulation substrate, a bottom surface adjacent to the base substrate, and a side surface which connects the top surface to the bottom surface, and
wherein a thickness of the barrier layer on the top surface and a thickness of the barrier layer on the side surface are the same.

9. The display panel of claim 1, wherein the first barrier layer is formed through an atomic layer deposition process, and the second barrier layer is formed through a chemical vapor deposition process.

10. A display panel, comprising:
a base substrate comprising
an emission area, and
a non-emission area around the emission area;
a light emitting element layer comprising
a pixel defining film configured to define the emission area and on the base substrate,
a first electrode on the base substrate,
an emission layer on the first electrode, and
a second electrode on the emission layer;
an encapsulation substrate on the light emitting element layer; and
a filling material between the light emitting element layer and the encapsulation substrate,
wherein the light emitting element layer further comprises
a spacer on the pixel defining film,
a capping layer on the spacer and overlapping the emission area and the non-emission area in plan view, and
a barrier layer on the capping layer and overlapping the emission area and the non-emission area in plan view,
wherein the barrier layer covers the capping layer and comprises a first barrier layer and a second barrier layer on the first barrier layer,
wherein the spacer comprises
a top surface adjacent to the encapsulation substrate,
a bottom surface adjacent to the base substrate, and
a side surface which connects the top surface to the bottom surface, and
wherein a thickness of the barrier layer on the top surface and a thickness of the barrier layer on the side surface are the same.

11. The display panel of claim 10, wherein a cross-section of the spacer has a reversed trapezoidal shape.

12. The display panel of claim 10, wherein a thickness of the second barrier layer is larger than a thickness of the first barrier layer.

13. The display panel of claim 10, wherein the spacer and the filling material are spaced from each other with the capping layer and the barrier layer between the spacer and the filling material.

14. The display panel of claim 10, wherein the second barrier layer comprises a same material as the first barrier layer.

15. The display panel of claim 10, wherein a thickness of the first barrier layer is 10 Å to 20 Å.

16. The display panel of claim 10, wherein a thickness of the second barrier layer is 10% or less of a thickness of the filling material.

17. The display panel of claim 10, wherein the first barrier layer is formed through an atomic layer deposition process, and the second barrier layer is formed through a chemical vapor deposition process.

18. An electronic device, comprising:
a display module comprising a display panel; and
a window module on the display module,
wherein the display panel comprises:
a base substrate comprising
an emission area, and
a non-emission area around the emission area;
a light emitting element layer comprising
a pixel defining film configured to define the emission area and on the base substrate,
a first electrode on the base substrate, an emission layer on the first electrode, and
a second electrode on the emission layer;
an encapsulation substrate on the light emitting element layer; and
a filling material between the light emitting element layer and the encapsulation substrate,
wherein the light emitting element layer further comprises
a spacer on the pixel defining film,
a capping layer on the spacer and overlapping the emission area and the non-emission area in plan view, and
a barrier layer on the capping layer and overlapping the emission area and the non-emission area in plan view,
wherein the barrier layer covers the capping layer and comprises a first barrier layer and a second barrier layer on the first barrier layer, and
wherein a density of the first barrier layer is higher than a density of the second barrier layer.

19. The electronic device of claim 18, further comprising at least one of a processor, a memory, or a power module.

20. The electronic device of claim 18, wherein the electronic device is at least one of a television, a monitor, an outdoor billboard, a personal computer, a notebook computer, a personal digital assistant, a vehicle instrument panel, a center fascia, a navigation unit, a room mirror display, a game console, a smartphone, a tablet computer, a smartwatch, smart glasses, a head mounted display, or a camera.
